(19) United States
(12) Patent Application Publication
(10) Pub. No.: US 2006/0192570 A1
(43) Pub. Date: Aug. 31, 2006

(54) Apparatus for monitoring consumable parts

(75) Inventors: Klemens Dworatzek, Edingen (DE); Duc Cuong Nguyen, Laatzen (DE)

Correspondence Address: CROWELL & MORING LLP;INTELLECTUAL PROPERTY GROUP, P.O. BOX 14300, WASHINGTON, DC, 20044-4300, US

(73) Assignee: MANN & HUMMEL GMBH, Ludwigsburg (DE)

(21) Appl. No.: 11/354,170

(22) Filed: Feb. 15, 2006

Related U.S. Application Data
(60) Provisional application No. 60/666,690, filed on Mar. 31, 2005.

(30) Foreign Application Priority Data
Feb. 15, 2005 (DE) 10 2005 007 020.5

(51) Int. Cl. G01R 27/08

(52) U.S. Cl. 324/699

(57) ABSTRACT

An apparatus for monitoring wearing or consumable parts 18, especially parts of internal combustion engines, in which monitoring verifies that the consumable part 18 is functioning and also ensures that a consumable part 18 conforming to specifications is used. The device has a maintenance switch 10, which is provided with a voltage supply 12 and a data line 13, which in turn is connected to a display 14, on which the monitoring result of the maintenance switch 10 is displayed. A chip 22 identifiable by a chip reader 23 is disposed in the consumable part 18. The chip reader 23 is integrated into the maintenance switch 10 and connected to the voltage supply 12 of the maintenance switch 10. This enables simple and cost-effective monitoring both of the functioning of the part and of the use of properly specified wearing or consumable parts.

### BACKGROUND OF THE INVENTION

The present invention relates to an apparatus for monitoring the functioning of consumable parts, such as parts of an internal combustion engine which wear out and need to be replaced.

The use of maintenance switches to monitor the functioning of filter elements is known in the art. For this purpose, the maintenance switch has a sensor that detects a specific functional characteristic of the filter, e.g., the pressure inside the filter housing. The maintenance switch has a voltage supply and a data line linked to a display. As soon as the filter element no longer functions as required, a corresponding signal is sent to the display via the data line. The display then indicates that the filter element must be replaced. The known maintenance switches, however, have the drawback that they do not check the filter element itself. Therefore, unsuitable or wrong filter elements can be installed, which may leave a downstream internal combustion engine unprotected and under some circumstances may damage the engine.

### SUMMARY OF THE INVENTION

It is therefore an object of the present invention to provide an improved apparatus for monitoring a consumable part.

Another object of the invention is to provide an apparatus for monitoring a consumable part that monitors both the functioning of the consumable part and the part itself.

A further object of the invention is to provide an apparatus for monitoring a consumable part which is cost-effective and requires little space for installation.

These and other objects are achieved in accordance with the present invention by providing an apparatus for monitoring a consumable part, the apparatus comprising a maintenance switch for monitoring functioning of the consumable part, the maintenance switch comprising a voltage supply and a data line connected to a display, wherein a chip identifiable by a chip reader is disposed in the consumable part, and a chip reader is integrated into the maintenance switch and connected to the voltage supply of the maintenance switch.

The apparatus according to the invention for monitoring consumable parts or parts which wear out comprises a maintenance switch. This maintenance switch senses characteristic data that reflect the operating condition of the consumable part. Depending on the condition of the consumable part, the characteristic data deviate from the defined ranges, so that the need to replace the consumable part can be identified. To this end, the maintenance switch is connected to a display via a data link. The maintenance switch further has a voltage supply to supply the power required to operate the maintenance switch.

The apparatus according to the invention for monitoring consumable parts is advantageous for use in motor vehicles because it requires little space for installation and can be easily integrated into an engine compartment of the motor vehicle. The monitoring of consumable parts of an internal combustion engine can be realized particularly advantageously with the device according to the invention. As used herein, the term “consumable part” refers to a component that is subject to wear or consumption or build-up of contaminants when used for its intended purpose. This includes, for example, filter elements for the intake air or the oil circuit of an internal combustion engine. However, other consumable parts such as electrodes, soot particle filters, tires, brake linings or exhaust systems may also be monitored.

The consumable part is provided with a chip, which can be identified by a chip reader. This chip may be incorporated in the consumable part during the manufacture of the part. One option in the manufacture of a plastic component is to incorporate the chip by injection-molding the plastic around it. However, the chip may also be glued, screwed or snapped onto the outside of the consumable part. The chip stores characteristic data that can be used to identify the consumable part. These data may include, for example, manufacturer data, such as the manufacturing date, the type designation, the serial number, or the like. To store the data, the chip in an installed consumable part requires no external power source.

The chip reader is configured in such a way that it can detect and retrieve the data from the chip installed in the consumable part. Thus, the chip reader can determine whether the specified consumable part has been installed. If a “wrong” component is installed, a corresponding message may be output, so that the proper component can be installed. The message that a “wrong” component has been installed may be output on a display. In addition, however, the startup of the internal combustion engine may also be prevented in order the prevent damage to the engine. Because the chip reader requires power to detect the data stored on the chip, it is connected to the voltage supply of the maintenance switch. This eliminates the need for an additional voltage supply for the chip reader, thereby saving additional cabling. This has a positive effect on the component costs, the required installation space and the installation of the device. It is furthermore advantageous if the chip reader is integrated into the housing of the maintenance switch. As a result, only a single component needs to be installed, and the chip reader is mounted at the correct location without any added complexity.

In accordance with one advantageous embodiment of the invention, the reader has an antenna, which is likewise integrated into the maintenance switch. The antenna is thus protected against damage and does not need to be mounted separately. The antenna is disposed at a location within the maintenance switch that is advantageous for detecting the chip data. Ideally, this location is the area lying closest to the chip, so that the antenna requires a minimum amount of power and cannot interfere with components in the vicinity.

In accordance with another advantageous embodiment of the invention, the reader is connected to the display via the data link of the maintenance indicator. It is technically readily feasible to separate the data of the maintenance switch from the data of the chip reader, so that a corresponding output to the display can be effected. The data may be output on a common display or on two separate displays, such that the one display indicates the operability of the consumable part and the other display indicates the use of a specified consumable part. Thus, the functioning of the consumable part can be monitored independently of the use of a consumable part conforming to specifications.

In a specific preferred embodiment of the invention, the consumable part or part which wears out and needs replacement is a filter element for filtering a fluid in an internal combustion engine. The fluid to be filtered may, for example, be the intake air or the lubricating oil of an internal combustion engine. By integrating the chip reader into the maintenance switch, the monitoring of such filter elements can be realized cost-effectively and with little complexity because these filter elements already have a maintenance switch with the corresponding voltage supply and data lines, so that monitoring of the installed filter element requires no additional installation space.

### BRIEF DESCRIPTION OF THE DRAWINGS

The invention will be described in further detail hereinafter with reference to illustrative preferred embodiments shown in the accompanying drawing figures, in which:

FIG. 1 is a schematic view of an apparatus according to the invention for monitoring a consumable part;

FIG. 2 is a view of a maintenance switch with integrated chip reader, and FIG. 3 is a cross-sectional view of a filter element associated with a monitoring apparatus according to the present invention.

### DETAILED DESCRIPTION OF PREFERRED EMBODIMENTS

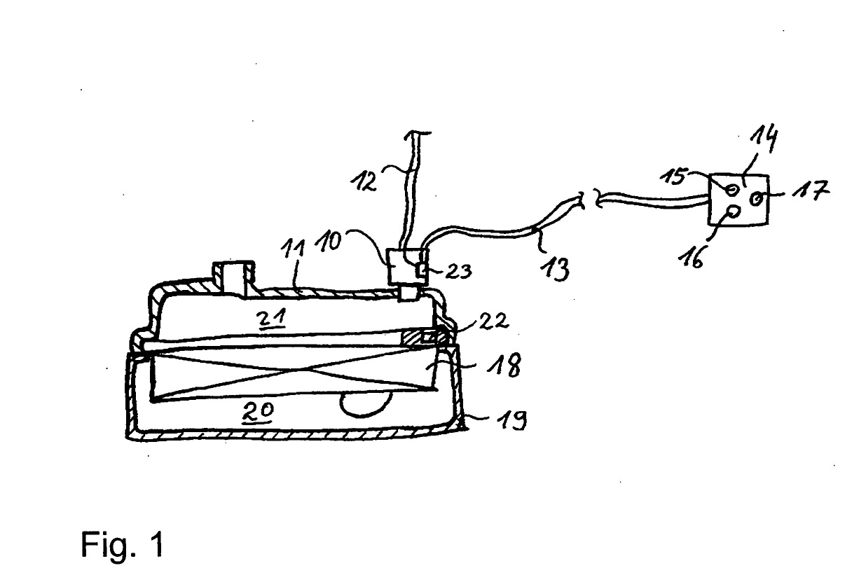

FIG. 1 schematically depicts an apparatus for monitoring consumable parts. The device comprises a maintenance switch 10, which is fixed to an upper housing part 11. The maintenance switch 10 is provided with a voltage supply 12. The voltage supply 12 is a line connecting a voltage or power source (not shown) to the maintenance switch 10. The maintenance switch further comprises a data line 13 which connects the maintenance switch 10 to a display 14. This data line 13 may be a cable, as shown. It is also possible, however, to use a radio or infrared-based data line.

The display 14 in this example has a red diode 15, a green diode 16 and a yellow diode 17. The red and green diodes 15, 16 are each connected to the maintenance switch 10. These diodes 15, 16 indicate the monitored operational state of a filter element 18. The filter element 18 is disposed between the upper housing part 11 and a lower housing part 19, such that an unfiltered side 20 is sealingly separated from a filtered side 21. As long as the filter element 18 is in functioning condition, this state is detected by the maintenance switch and transmitted to the display 14. To indicate visually that the filter element 18 is in proper condition, the green diode 16 lights up. As soon as the filter element 18 is dirty or its functioning is impaired, this state is detected by the maintenance switch 10 and transmitted to the display 14, so that the red diode 15 lights up. This indicates that the filter element 18 must be replaced.

The filter element 18 is provided with an integrated chip 22 on which element-specific data are stored. A chip reader 23 integrated into the maintenance switch 10 reads and evaluates the data stored on the chip. The chip reader 23 is connected to the voltage supply 12, so that sufficient power is available for the reading or evaluation process. The chip reader is further connected to the data line 13, so that the data detected by the chip reader 23 can be transmitted to the display 14. If the data detected by the chip reader 23 correspond to the required specifications for the engine, no warning is output on the display. If the detected data do not correspond to the specifications, a signal is sent to the display 14 via the data line 13, and the yellow diode 17 blinks. This makes it possible to visually detect whether a specified filter element is installed in the housing 11, 19. Of course the display 14 may also have other visual or acoustic outputs known in the art to display the operational state of the filter or the use of a filter element 18 conforming to the specifications.

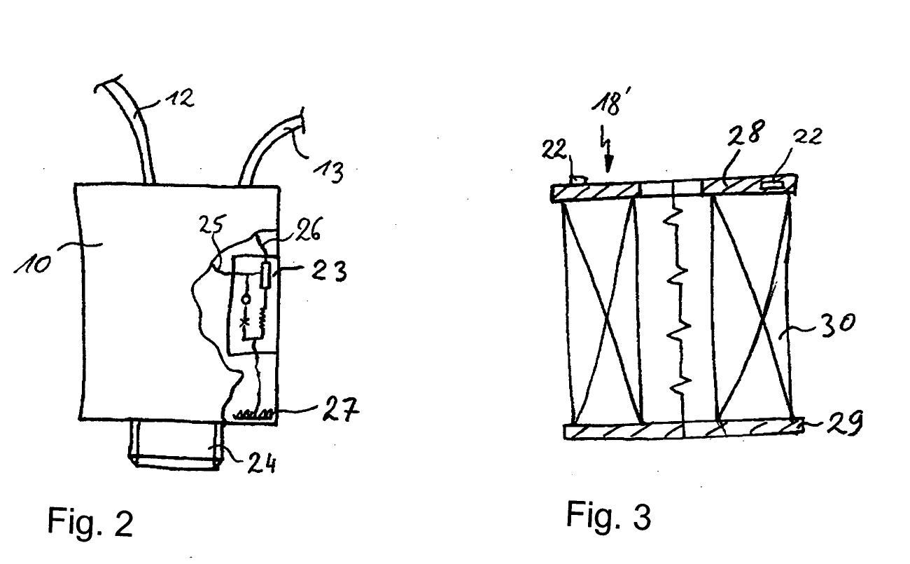

FIG. 2 schematically illustrates a maintenance switch 10. Parts corresponding to those shown in FIG. 1 are identified by the same reference numerals. The maintenance switch 10 has a threaded connection 24 with which the maintenance switch 24 can be fixed to the upper housing part 11 (illustrated in FIG. 1). The chip reader 23 is connected to the voltage supply 12 via a cable 25. An additional cable 26 connects the chip reader 23 to the data line 13.

An antenna 27 connected to the chip reader 23 is integrated into the maintenance switch 10. The antenna 27 is configured in such a way that it can detect signals transmitted by the chip 22 (illustrated in FIGS. 1 and 3). To this end, the antenna 27 is disposed in the lower region of the maintenance switch 10, so that the distance to be bridged between the chip 22 and the antenna 27 can be kept to a minimum. In other embodiments, the antenna 27 is disposed directly on the chip reader 23 so that a connecting cable between the antenna and the chip reader 23 is eliminated.

FIG. 3 depicts a filter element 18′ in cross section. The filter element 18′ shown is a cylindrical filter element with an upper end disk 28 and a lower end disk 29. A filter member 30 for filtering the fluid extends between the end disks 28, 29.

In the left half of FIG. 3, the chip 22 is glued to the upper end disk 28 of the filter element 18′ and is therefore permanently connected to the end disk 28.

In the right half of FIG. 3, the chip 22 is incorporated into the upper end disk 28. This may be done during the manufacture of the upper end disk 28, for example. To accomplish this, the chip 22 is inserted into the injection mold and the plastic for the end disk is injected around the chip 22. As an alternative, a recess for inserting the chip 22 may be provided in the end disk 28, and the recess subsequently sealed after insertion of the chip.

The foregoing description and examples have been set forth merely to illustrate the invention and are not intended to be limiting. Since modifications of the describe embodiments incorporating the spirit and substance of the invention may occur to persons skilled in the art, the invention should be construed broadly to include all variations within the scope of the appended claims and equivalents thereof.

What is claimed is:

1. An apparatus for monitoring a consumable part, said apparatus comprising a maintenance switch for monitoring functioning of the consumable part, said maintenance switch comprising a voltage supply and a data line connected to a display, wherein a chip identifiable by a reader is disposed in the consumable part, and said reader is integrated into the maintenance switch and connected to the maintenance switch voltage supply.

2. An apparatus according to claim 1, wherein said reader comprises an antenna which is integrated into the maintenance switch.

3. An apparatus according to claim 1, wherein the reader is connected to the display via the maintenance switch data line.

4. An apparatus according to claim 1, wherein the consumable part is a filter element for filtering a fluid of an internal combustion engine.
